(19) United States
(12) Patent Application Publication
(10) Pub. No.: US 2012/0181660 A1
(43) Pub. Date: Jul. 19, 2012

(54) SEMICONDUCTOR DEVICE

(75) Inventor: Naonori FUJIWARA, Chuo-ku (JP)

(73) Assignee: ELPIDA MEMORY, INC., Tokyo (JP)

(21) Appl. No.: 13/350,432

(22) Filed: Jan. 13, 2012

(30) Foreign Application Priority Data
Jan. 14, 2011 (JP) 2011-005885

(51) Int. Cl. H01L 29/92

(52) U.S. Cl. 257/532; 257/E29.342

(57) ABSTRACT

A semiconductor device comprises a capacitor, the capacitor including a lower electrode, a dielectric film containing crystalline zirconium oxide formed on the lower electrode, and an upper electrode containing a titanium nitride film contacting to the dielectric film, wherein the dielectric film comprises an amorphous film on an interface with the titanium nitride film, thereby preventing the reduction of the thickness of the titanium nitride film formed on the dielectric electrode with a low leakage current and a high dielectric constant.

### BACKGROUND OF THE INVENTION

1. Field of the Invention

The present invention relates to a semiconductor device, particularly, a capacitor structure.

2. Description of the Related Art

A DRAM (Dynamic Random Access Memory) is used for a computer and other electronic devices as a semiconductor device capable of high speed operation. A DRAM generally includes a memory cell array and a peripheral circuit for operating the same. The memory cell array includes a plurality of matrix arrayed unit components having a switching transistor and a capacitor.

Like other semiconductor devices, each cell in a DRAM is miniaturized to meet high integration. As a result, a plane area used to form a capacitor narrows, and thus, it is difficult to have a necessary capacity as a memory device. In order to solve such problem, it has been attempted to make an electrode have a three-dimensional structure, to make upper and lower electrodes with metal materials (MIM structure), and to make a capacitor insulating film have a high dielectric constant. As a result, a DRAM in an area having a minimum feature size F (one of standard technology levels) of 70 nm comprises an electrode having a three-dimensional structure as an essential component. Also, a DRAM with upper and lower electrodes made of metal materials was already commercialized. Therefore, it is difficult to expect to further develop the properties of a capacitor based on such technology. The last solution to further miniaturize cells in a DRAM is to make a capacitor insulating film have a high dielectric constant to improve the properties of a capacitor.

With respect to making an insulating film have a high dielectric constant, if a zirconium oxide film (hereinafter referred to as “ZrO”) is crystallized, it will have a relative dielectric constant of 35 in a cubic structure and a higher relative dielectric constant of 45 in a tetragonal structure. Also, because it has a band gap of 5.8 eV, it is effective in controlling leakage current. However, a crystalline film has a problem of increasing leakage current through a grain boundary.

In order to control leakage current, it has been suggested to make the entire of a dielectric film be an amorphous film. It is possible to prevent leakage current resulted from a grain boundary by making the entire of a dielectric film be an amorphous film. In order to form an amorphous film, JP 2007-158222 A discloses that a base electrode layer is formed to be an amorphous film, so that a crystalline film is not formed thereon. However, because an amorphous dielectric film has a lower relative dielectric constant than a crystalline dielectric film, it should become thicker to have a desired capacity. JP 2007-266474 A discloses that it is possible to obtain an amorphous dielectric film with a high relative dielectric constant of 30 or more by adding oxides of elements having a large ionic radius, for example, adding Y, La, etc. to a HfO film, a ZrO film, etc. However, an amorphous dielectric film obtained such process still has a lower relative dielectric constant than a ZrO film.

In order to control leakage current by use of a crystalline ZrO film, JP 2006-135339A uses a ZrO/AlO/ZrO (hereinafter referred to as “ZAZ”) structure and a ZrO/AlO stack (hereinafter referred to as “ZA”) structure, which combine a crystalline ZrO film (1) and an amorphous aluminum oxide film (hereinafter referred to as “AlO” film (2)) (see FIGS. 1 and 2). It is possible to control leakage current through a grain boundary of a single-layered ZrO film by using an amorphous AlO film.

However, a ZAZ structure and a ZA structure have a problem that the thickness of a titanium nitride electrode formed as an upper electrode of a capacitor thereon becomes thin. For example, even though a titanium nitride electrode is formed as a film to have a desired thickness of 10 nm by CVD, the film actually has a thickness of about 6 nm on the ZAZ structure. Additionally, if the thickness of an upper titanium nitride electrode becomes thin, a quality product yield reduces. The same problem occurs in case of the ZA structure.

Sputtering, etc., for physically depositing titanium nitride films can obtain thicker films, but has very low coverage. Therefore, sputtering is not applicable to a capacitor having a three-dimensional structure.

### SUMMARY

One embodiment of the present invention provides a semiconductor device comprising a capacitor, which the capacitor includes a lower electrode, a dielectric film including crystalline zirconium oxide formed on the surface of the lower electrode, and an upper electrode including a titanium nitride film, which contacts the dielectric film, formed on the dielectric film, wherein the dielectric film includes an amorphous film on an interface with the titanium nitride film of the upper electrode.

According to one embodiment of the present invention, it is possible to prevent the reduction of quality product yield due to make the thickness of the titanium nitride film in the upper electrode thin.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic diagram of a conventional dielectric film having a ZAZ structure.

FIG. 2 is a schematic diagram of a conventional dielectric film having a ZA structure.

FIG. 3 shows the dependency of a thickness of a titanium nitride film to a base.

FIG. 4 is a schematic cross section view of a semiconductor device according to one embodiment of the present invention.

FIG. 5 is a schematic diagram of a dielectric film according to Example 1.

FIG. 6 is a flow chart showing an ALD sequence of a dielectric film according to Example 1.

FIG. 7 is an ALD timing chart of a dielectric film according to Example 1.

FIG. 8 shows the dependency of a relative dielectric constant of a ZrO film subjected to anneal for crystallization to a thickness thereof.

FIG. 9 is a schematic diagram of a dielectric film according to Example 2.

FIG. 10 is a flow chart showing an ALD sequence of a dielectric film according to Example 2.

FIG. 11 is an ALD timing chart of a dielectric film according to Example 2.

FIG. 12 is a schematic diagram of a dielectric film according to Example 3.

FIG. 13 is a flow chart showing an ALD sequence of a dielectric film according to Example 3.

FIG. 14 is an ALD timing chart of a dielectric film according to Example 3.

FIG. 15 shows the relationship between the Al concentration and dielectric constant of a ZrAlO film subjected to anneal for crystallization.

FIG. 16 shows a graph of the leakage currents of capacitors prepared in each Example.

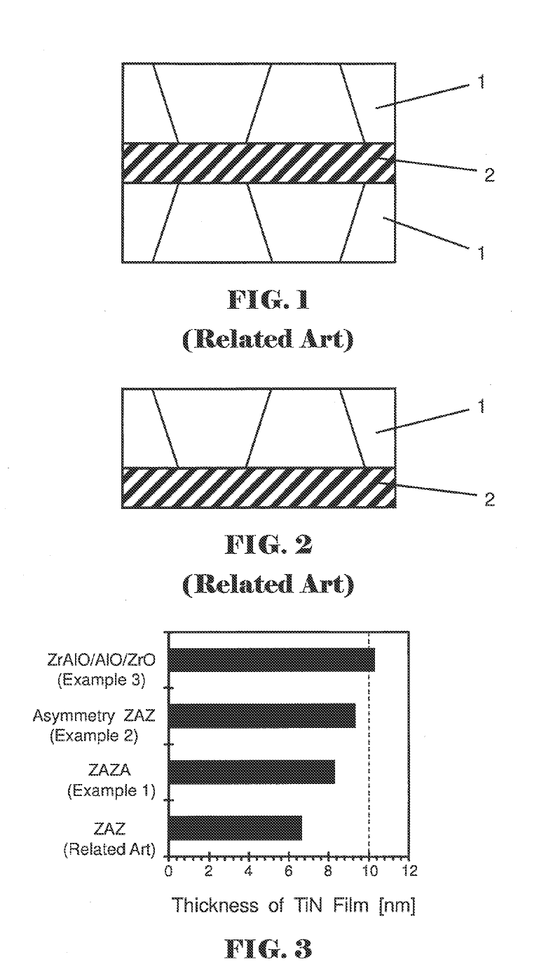

### DETAILED DESCRIPTION OF THE REFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

### Example 1

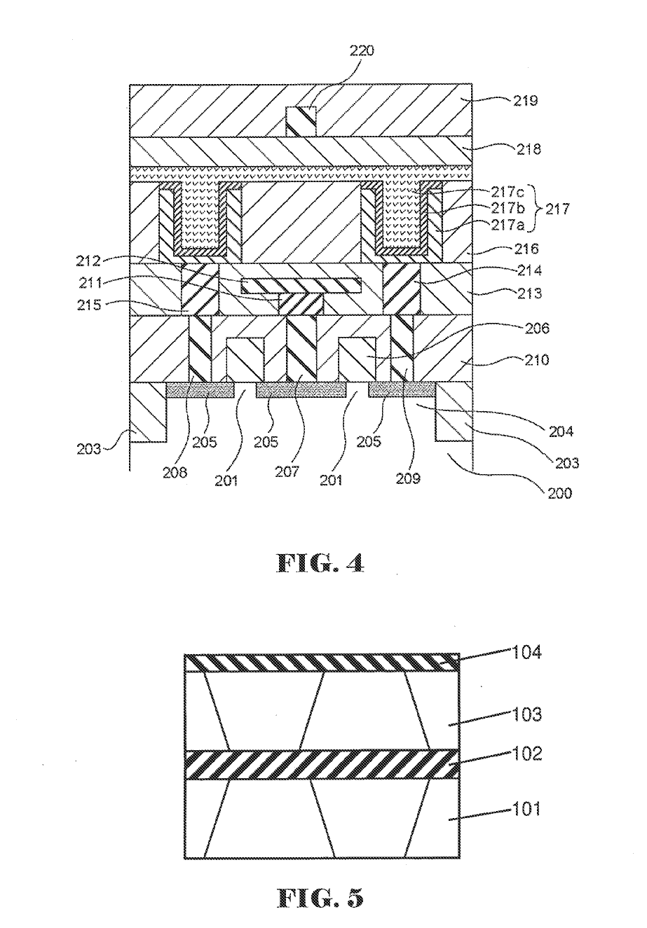

FIG. 4 is a schematic cross sectional view of a DRAM including a memory cell to which a capacitor according to one embodiment of the present invention is applied.

In the DRAM shown in FIG. 4, for fabricating MOS transistor 201 that is a switching element in a memory cell of the DRAM on semiconductor substrate 200, element isolation region 203 is formed in the semiconductor substrate to partition active region 204 in which a memory cell is formed. The element isolation region 203 is formed by a process known in the art, such as STI (Shallow Trench Isolation) method. Diffusion layer region 205 that is a source or drain region of MOS transistor 201 is formed in active region 204, and gate electrode 206 is formed on semiconductor substrate 200 by interposing a gate insulating film (not shown). The gate electrode 206 is formed to have a line shape over a plurality of active regions 204 to be a word line. The example in FIG. 4 shows a memory cell having two MOS transistors, which share one diffusion layer region (for convenience, referred to as a “source region”). However, the present invention is not limited to such a structure. Cell contact plugs 207, 208, 209 penetrating first interlayer insulating film 210 contacts each diffusion layer. The cell contact plug 207 contacting the source region is connected to bit line 212 by interposing via plug 211. The cell contact plugs 208, 209 contacting two diffusion layers (for convenience, referred to as a “drain region”), which are not shared by two MOS transistors, respectively, are connected to storage-node contact plugs 214, 215 that penetrate second interlayer insulating film 213. Each capacitor 217 contacts the storage-node contact plug 214, 215. The capacitor 217, which has been formed by using third interlayer insulating film 216 as a template, includes lower electrode 217a formed to have a three-dimensional structure (a cylinder structure in this embodiment), dielectric film 217b formed in the internal side of the lower electrode 217a, and upper electrode 217c formed on the dielectric film 217b. Also, the upper electrode 217c includes at least a TiN film on the surface of the dielectric film 217b and can further include an impurity doped polysilicon film and a metal plate electrode, such as W, on the TiN film. The DRAM is completed by forming fourth interlayer insulating film 218, upper wiring layer 220, fifth interlayer insulating film 219 overlaying the upper wiring layer 220, or the like.

The example in FIG. 4 explains the simplest structure in which a planar type MOS transistor is used and a cylinder type lower electrode is used as a capacitor having a three-dimensional structure. However, the present invention is not limited to have such structure. A recess gate type MOS transistor can be used as an MOS transistor, and a pedestal-shaped capacitor using an outer wall of a lower electrode and a crown-shaped capacitor using outer and inner walls of a lower electrode can be used as a capacitor.

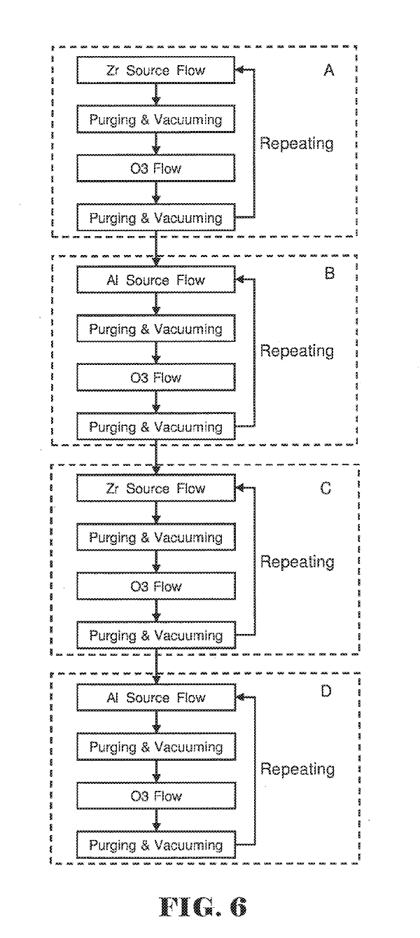

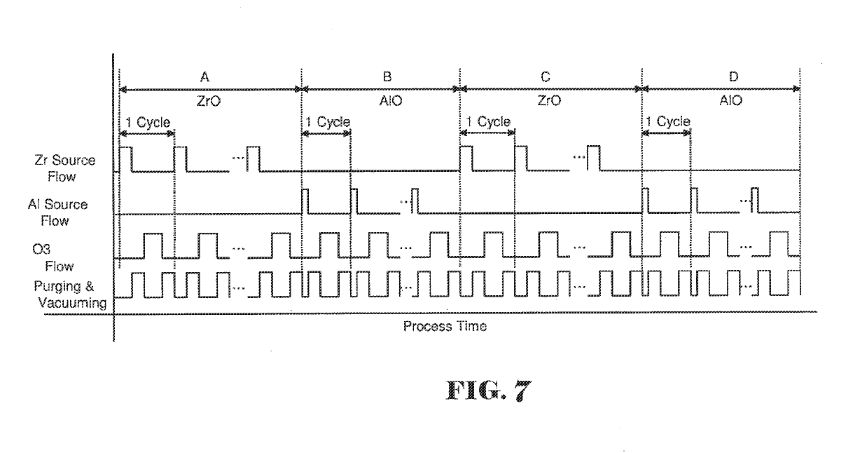

As shown in FIG. 5, the dielectric film in a capacitor according to Example 1 has a ZAZA structure, in which first zirconium oxide (hereinafter referred to as “ZrO”) film 101, first aluminum oxide (hereinafter referred to as “AlO”) film 102, second ZrO film 103, and second AlO film 104 are laminated in order on a titanium nitride lower electrode (not shown). The first and second ZrO films 101, 103 are crystalline and the first and second AlO films 102, 104 are amorphous. Such films are formed by ALD (Atomic Layer Deposition) method having good step coverage. FIG. 6 shows the ALD sequence of Example 1. FIG. 7 is an ALD timing chart of a dielectric film according to Example 1. As a zirconium material gas (hereinafter referred to as a “Zr source”) to form the ZrO film, for example, TEMAZ (tetrakis(ethylmethylamino) zirconium) can be used. Also, as an aluminum material gas (hereinafter referred to as an “Al source”) to form the AlO film, for example, TMA (trimethyl aluminum) can be used. Also, O₃ (ozone) is used as an oxidizing gas needed for oxidation reaction.

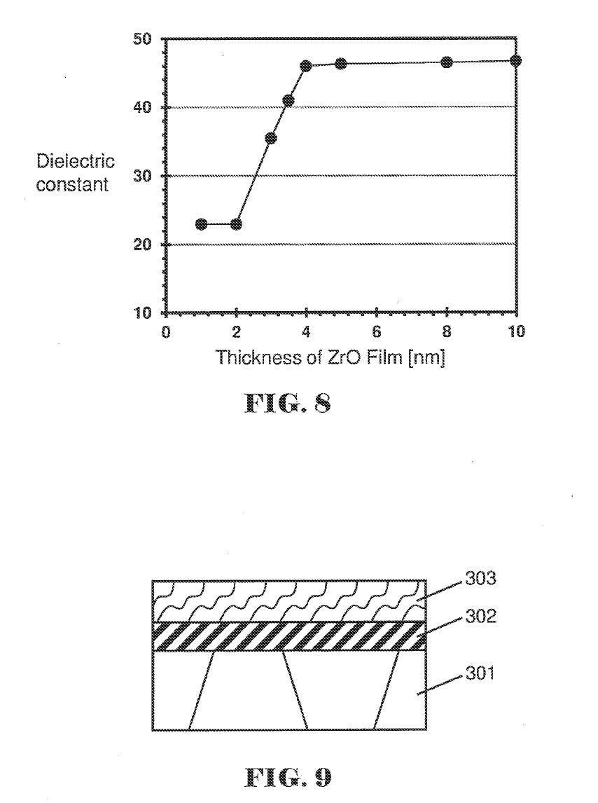

Firstly, first ZrO film 101 is formed. In sequence A for forming the first ZrO film (ZrO film forming sequence) in FIG. 6, a Zr source is supplied to a reaction chamber to absorb the Zr source onto the surface of the titanium nitride lower electrode (Zr Source Flow), and then unabsorbed Zr source is removed from the reaction chamber by purging and vacuuming (Purging & Vacuuming). Subsequently, O₃ gas is supplied into the reaction chamber to react O₃ gas with the Zr source absorbed onto the surface of the lower electrode (base layer) so as to prepare zirconium oxide (O3 Flow), and then unreacted O₃ gas and decomposition products are removed by purging and vacuuming (Purging & Vacuuming). In sequence A, these processes as one cycle are repeated so as to obtain the first ZrO film having a desired thickness. FIG. 8 shows the dependency of a relative dielectric constant of a ZrO film subjected to annealing for crystallization to a thickness thereof. As a ZrO film becomes thinner, its relative dielectric constant reduces. Therefore, the thickness of the crystalline ZrO film is set to 4 to 10 nm and preferably to 4 to 6 nm.

Subsequently, first AlO film 102 is formed. As done in the sequence A, in sequence B for forming the first AlO film 102, an Al source is supplied to a reaction chamber to absorb the Al source onto the surface of the first ZrO film 101 (Al Source Flow), and unabsorbed Al source is removed from the reaction chamber by purging and vacuuming (Purging & Vacuuming). Subsequently, O₃ gas is supplied into the reaction chamber to react O₃ gas with the Al source absorbed onto the surface of the base layer so as to form AlO (O3 Flow and Purging & Vacuuming). The first AlO film having a desired thickness can be obtained by repeating such AlO film forming cycles. Because the first AlO film 102 has a thickness enough to separate the first ZrO film 101 and the second ZrO film 103, the thickness is set to 0.3 to 1.0 nm and preferably to 0.3 to 0.5 nm.

Similarly, second ZrO film 103 and second AlO film 104 are formed by the same processes as mentioned above (referred to as ZrO film forming sequence C and AlO film forming sequence D, respectively). Similar with the first ZrO film 101, the thickness of the second ZrO film 103 is set to 4 to 10 nm and preferably to 4 to 6 nm. On the other hand, since the second AlO film 104 aims to cap the ZrO film, the thickness of second AlO film 104 is preferably set to 0.1 to 0.5 nm.

In order to uniformly form a film on a three-dimensional structure, it is preferable to supply the Zr source (TEMAZ) and the Al source (TMA) for 30 seconds and 90 seconds, respectively. In order to more sufficiently remove impurity from a film, it is preferable to supply O₃ gas for 300 seconds. Also, when a film is formed by ALD, it is necessary to form a film at a temperature lower than a temperature at which each material gas is decomposed. The temperature is preferably 300° C. or less when the foregoing material gases are used. At such temperature, a ZrO film is formed in a microcrystalline state, and not in a polycrystalline state having a clear grain boundary. However, the crystallization of ZrO film to the polycrystalline state is performed during the step of increasing a temperature by thermal CVD for forming a titanium nitride film as an upper electrode. Both AlO films are not crystallized and are in an amorphous state even though the temperature increases during the step of forming a titanium nitride film, because thicknesses of both AlO films is not enough to change it into polycrystalline state and the crystallization temperature of AlO is high.

Subsequently, a capacitor is provided by forming an upper electrode including a titanium nitride film contacting with the dielectric film having the above ZAZA structure. Considering the application to a three-dimensional structure, the titanium nitride film is formed by CVD using titanium tetrachloride (TiCI₄) and ammonia (NH₃) as reaction gases. The titanium nitride film is deposited at 450° C. and is configured to have a thickness of 10 nm.

In Example 1, the crystallization of ZrO film is performed by increasing a temperature when forming the TiN upper electrode. Alternatively, the crystallization of ZrO film can be performed by annealing prior to forming the TiN upper electrode.

Also, in Example 1, the first ZrO film, the second AlO film and the second ZrO film are deposited in succession. Alternatively, it is possible to perform crystallization annealing after forming each ZrO film, such as forming a first ZrO film, performing crystallization annealing, forming a first AlO film, forming a second ZrO film, performing crystallization annealing, and then forming a second AlO film. Such a crystallization annealing can be performed at 350° C. or more, preferably at 400° or more. Also, the crystallization annealing can be performed in any atmosphere. In order to prevent the oxidation of a TiN film in a lower electrode, the crystallization annealing is preferably performed in a non-oxidative atmosphere, for example, in an inert gas, such as nitrogen gas, or can be performed in an ammonia gas atmosphere when it is concurrently performed with the increase in a temperature when forming TiN upper electrode.

As shown in FIG. 3, since the ZAZA structure is used as a dielectric film in Example 1, a titanium nitride film in an upper electrode is recovered to have a thickness of about 8 nm and can prevent the titanium nitride film from being thinner when compared with the conventional ZAZ structure.

### Example 2

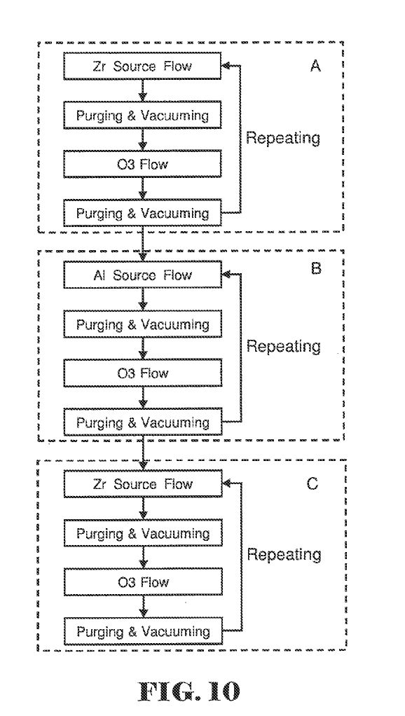

As shown in FIG. 9, the dielectric film in a capacitor according to Example 2 has an asymmetric ZAZ structure in which first ZrO film 301, AlO film 302 and second ZrO film 303 are laminated in this order on a titanium nitride lower electrode (not shown) and the second ZrO film 303 is thinner than the first ZrO film 301. As done in Example 1, the first ZrO film 301 is a crystalline film, but the second ZrO film 303 is an amorphous film. FIG. 10 shows film forming sequences according to Example 2 and FIG. 11 is a timing chart according to Example 2.

As done in Example 1, the asymmetric ZAZ structure in Example 2 is formed by ALD method. Since the first ZrO film is a crystalline film, the thickness thereof is set to 4 to 10 nm and preferably to 4 to 6 nm as discussed in Example 1. The thickness of AlO film 302 is also set to 0.3 to 1.0 nm and preferably to 0.3 to 0.5 nm for separating ZrO films. In order to make the second ZrO film into an amorphous film, the thickness thereof is set to 2 nm or less and preferably to 1.0 to 2.0 nm.

Subsequently, a capacitor is provided by forming an upper electrode including a titanium nitride film formed onto the dielectric film having such asymmetric ZAZ structure. As done in Example 1, the titanium nitride film is formed by thermal CVD method.

In Example 2, the crystallization of the first ZrO film is performed by increasing a temperature when forming a titanium nitride film as an upper electrode. Alternatively, the crystallization can be performed by annealing prior to forming the titanium nitride film. On the other hand, since the second ZrO film is thin, it is not crystallized and remains amorphous state.

Also, In Example 2, the depositions for the first ZrO film, the AlO film and the second ZrO film are continuously performed. Alternatively, it is possible to perform crystalline annealing after forming the first ZrO film, and thereafter to form the AlO film and the second ZrO film in order.

As shown in FIG. 3, it was found that the asymmetric ZAZ structure in Example 2 can further prevent the titanium nitride film as an upper electrode from being thinner when compared with Example 1.

### Example 3

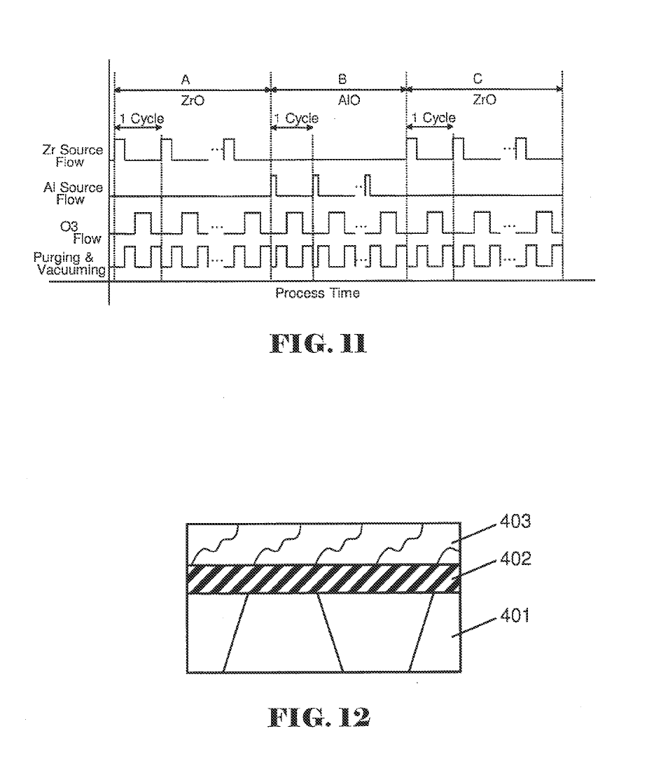

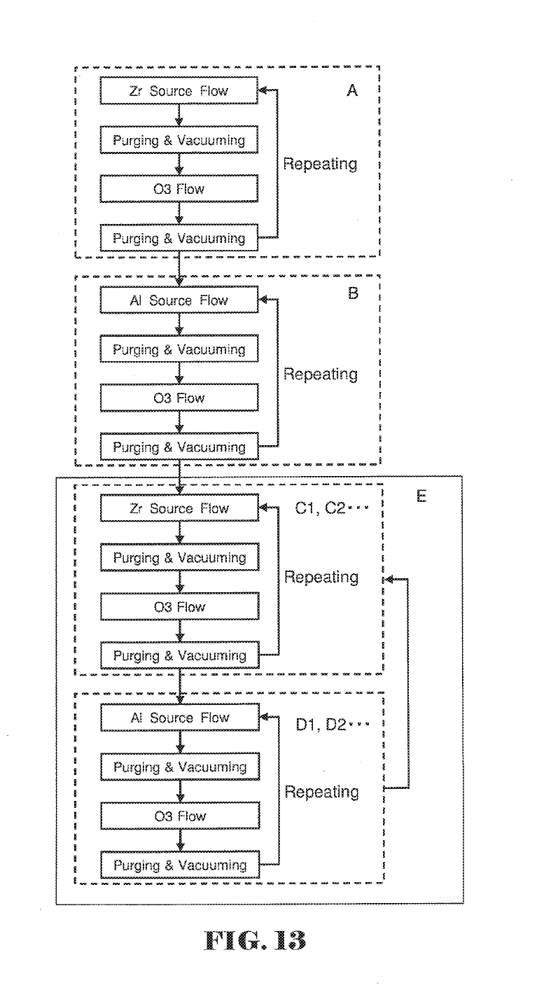

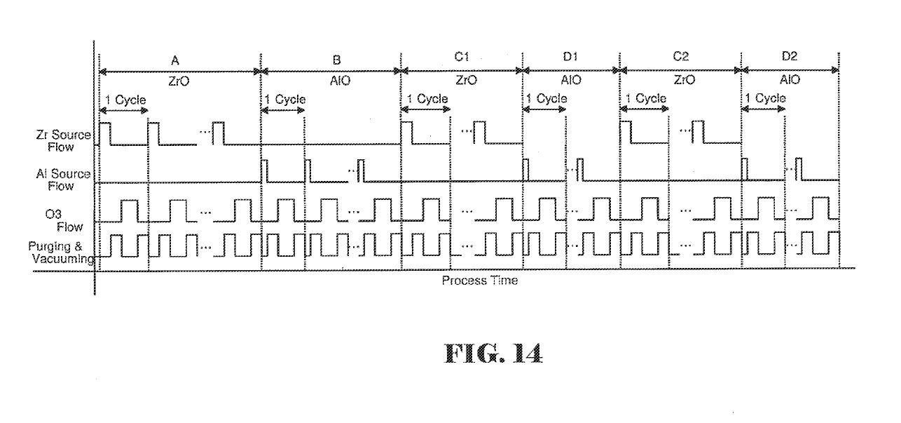

As shown in FIG. 12, the capacitor according to Example 3 includes a dielectric film having a ZrAlO/AlO/ZrO structure, in which first ZrO film 401, AlO film 402 and ZrAlO film 403 are laminated in this order on a titanium nitride lower electrode (not shown). The ZrO film 401 is crystalline and the AlO film is amorphous. The ZrAlO film 403 is a lamination of amorphous films, in which a ZrO film and an AlO film are alternately formed. FIG. 13 shows film forming sequences according to Example 3 and FIG. 14 is a timing chart according to Example 3. As shown in FIGS. 13 and 14, sequence A forming ZrO film 401 and sequence B forming AlO film 402 are same as Examples 1 and 2. Sequence E forming ZrAlO film 403 alternately repeats ZrO film forming sequences (C1, C2 . . . ) and AlO film forming sequences (D1, D2 . . . ). This example performs one cycle in each of AlO film forming sequences (D1, D2 . . . ). However, the present invention is not limited to perform such one cycle.

As done in Examples 1 and 2, the ZrAlO/AlO/ZrO structure of Example 3 is formed by ALD method. In order to make the ZrO film 401 into a crystalline film, the thickness thereof is also set to 4 to 10 nm and preferably to 4 to 6 nm. Also, in order to terminate the first ZrO film with the AlO film 402, the thickness of the AlO film is set to 0.3 to 1.0 nm and preferably to 0.3 to 0.5 nm.

The thickness of ZrAlO film 403 is set to 1.0 to 5.0 nm and preferably to 1.0 to 2.0 nm. FIG. 15 shows the Al concentration and dielectric constant of an annealed ZrAlO film. If the Al concentration is less than 5 atomic %, the crystallization of ZrAlO film causes, while if the Al concentration is greater than 10 atomic %, the relative dielectric constant of the ZrAlO film much reduces. To obtain the amorphous ZrAlO film 403 without much reducing the relative dielectric constant, the Al concentration is preferably in a range of 5 to 10 atomic % as metal atomic ratio represented by Al/(Al+Zr). Also, either a ZrO film or an AlO film can be used as the topmost layer of the ZrAlO film. Preferably, an AlO layer is used as the topmost layer.

The Al concentration in the ZrAlO film is controlled to be 5 to 10 atomic %, but the Al distribution in the ZrAlO film is needless to be uniform as long as the ZrAlO film is amorphous.

Subsequently, a capacitor is provided by forming an upper electrode including a titanium nitride film formed onto the dielectric film having the ZrAlO/AlO/ZrO structure.

In Example 3, the crystallization of the ZrO film 401 is performed by increasing a temperature when forming a titanium nitride film as an upper electrode. Alternatively, the ZrO film 401 can be crystallized by annealing it prior to forming a titanium nitride film.

In Example 3, the ZrO film, the AlO film and the ZrAlO film are continuously formed. Alternatively, it is possible to perform crystallization annealing after forming the ZrO film 401, and thereafter to form the AlO film 402 and the ZrAlO 403 film in order.

As shown in FIG. 3, it was found that the ZrAlO/AlO/ZrO structure in Example 3 can further prevent the titanium nitride film as an upper electrode from being thinner when compared with Examples 1 and 2.

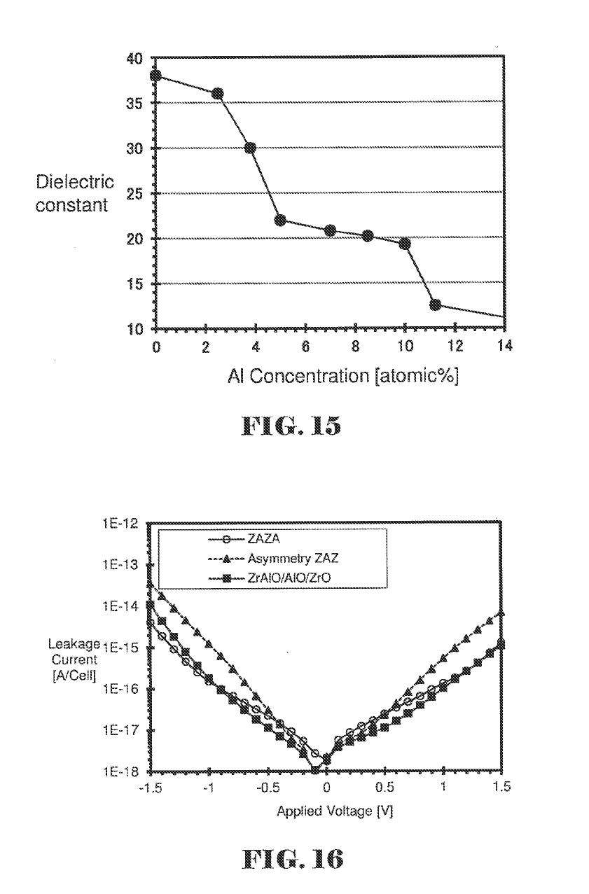

FIG. 16 shows the leakage currents of capacitors prepared in each example. As shown in FIG. 16, the capacitor formed in Example 3 has an excellent leakage current property when compared with that formed in Example 2.

Also, the present invention includes the following aspects:
I. A method for manufacturing a semiconductor device, comprising:

forming a capacitor lower electrode on a semiconductor substrate;

forming a dielectric film including a crystalline zirconium oxide on the lower electrode; and

forming an upper electrode including a titanium nitride film, which contacts to the dielectric film, on the dielectric film,

wherein the forming the dielectric film comprises forming a dielectric film having an amorphous state as the topmost surface layer thereof.
II. The method according to Item I, wherein the forming the dielectric film is performed by an atomic layered deposition (ALD) method and comprises forming an AlO film on a ZrO film.
III. The method according to Item II, wherein the forming the dielectric film comprises forming a first ZrO film having a thickness of 4 to 10 nm, a first AlO film having a thickness of 0.3 to 1.0 nm, a second ZrO film having a thickness of 4 to 10 nm and a second AlO film having a thickness of 0.1 to 0.5 nm in order from the lower electrode, and comprises a thermal treatment for crystallizing the first and second ZrO films.
IV. The method according to Item II, wherein the forming the dielectric film comprises forming a first ZrO film having a thickness of 4 to 10 nm, a first AlO film having a thickness of 0.3 to 1.0 nm and a second ZrO film having a thickness of 2 nm or less in order from the lower electrode, and comprises a thermal treatment for crystallizing the first ZrO film.
V. The method according to Item II, wherein the forming the dielectric film comprises forming a first ZrO film having a thickness of 4 to 10 nm, a first AlO film having a thickness of 0.3 to 1.0 nm, and a ZrAlO film having a structure, in which second zirconium oxide films and second amorphous aluminum oxide films are alternately laminated, and having a total thickness of 1 to 5 nm in order from the lower electrode, and comprises a thermal treatment for crystallizing the first ZrO film.
VI. The method according to Item V, wherein the concentration of Al in the ZrAlO film is in the range of 5 to 10 atomic % as metal atomic ratio represented by Al/(Al+Zr).
VII. The method according to Item V or VI, wherein the thickness of each second zirconium film in the ZrAlO film is 2 nm or less, and an interface with the upper electrode is an AlO film.
VIII. The method according to any one of Items I to VII, wherein titanium nitride as the upper electrode is formed by CVD or ALD method.
IX. The method according to Item VIII, wherein heating a substrate when forming the titanium nitride as a film also serves as a thermal treatment for the crystallization to form the crystalline zirconium nitride film.
X. The method according to any one of Items I to IX, wherein the lower electrode is formed to have a three-dimensional structure.

What is claimed is:

1. A semiconductor device comprising a capacitor, which the capacitor comprises:
a lower electrode;
a dielectric film comprising crystalline zirconium oxide formed on the surface of the lower electrode; and
an upper electrode comprising a titanium nitride film, which contacts the dielectric film, formed on the dielectric film,
wherein the dielectric film comprises an amorphous film on an interface with the titanium nitride film of the upper electrode.

2. The semiconductor device according to claim 1, wherein the dielectric film comprises crystalline zirconium oxide and amorphous aluminum oxide.

3. The semiconductor device according to claim 2, wherein the dielectric film has a structure, in which a first zirconium oxide film, a first aluminum oxide film, a second zirconium oxide film and a second aluminum oxide film are laminated from the lower electrode; the first and second zirconium oxide films are crystalline, and the first and second aluminum oxide films are amorphous.

4. The semiconductor device according to claim 3, wherein the thicknesses of the first and second zirconium oxide films are in the range of 4 to 10 nm, the thickness of the first aluminum oxide film is in the range of 0.3 to 1.0 nm, and the thickness of the second aluminum oxide film is in the range of 0.1 to 0.5 nm.

5. The semiconductor device according to claim 2, wherein the dielectric film has a structure in which a first zirconium oxide film, a first aluminum oxide film and a second zirconium oxide film are laminated from the lower electrode; the first zirconium oxide film is crystalline; and the first aluminum oxide film and the second zirconium oxide film are amorphous.

6. The semiconductor device according to claim 5, wherein the thickness of the first zirconium oxide film is in the range of 4 to 10 nm, the thickness of the first aluminum oxide film is in the range of 0.3 to 1.0 nm, and the thickness of the second zirconium oxide film is 2 nm or less.

7. The semiconductor device according to claim 2, wherein the dielectric film has a structure in which a first crystalline zirconium oxide film, an first amorphous aluminum oxide film, and an amorphous ZrAlO film are laminated from the lower electrode; and wherein second zirconium oxide films and second amorphous aluminum oxide films are alternately laminated in the amorphous ZrAlO film.

8. The semiconductor device according to claim 7, wherein the thickness of the first zirconium oxide film is in the range of 4 to 10 nm, the thickness of the first aluminum oxide film is in the range of 0.3 to 1.0 nm, and the thickness of the ZrAlO film is in the range of 1 to 5 nm.

9. The semiconductor device according to claim 7, wherein the concentration of Al in the ZrAlO film is in the range of 5 to 10 atomic % as metal atomic ratio represented by Al/(Al+Zr).

10. The semiconductor device according to claim 7, wherein the thickness of each second zirconium film in the ZrAlO film is 2 nm or less, and a face contacting the titanium nitride film of the upper electrode is the second aluminum oxide film.

11. The semiconductor device according to claim 10, wherein each second aluminum oxide film formed between the second zirconium oxide films in the ZrAlO film has a thickness formed by performing one ALD cycle.

12. The semiconductor device according to claim 1, wherein the lower electrode has a three-dimensional structure.

13. The semiconductor device according to claim 12, wherein the lower electrode has a cylinder shape and the dielectric film is formed on an inner wall of the lower electrode.

14. The semiconductor device according to claim 12, wherein the lower electrode has a pedestal shape and the dielectric film is formed on an outer wall of the lower electrode.

15. The semiconductor device according to claim 12, wherein the lower electrode has a crown shape and the dielectric film is formed on inner and outer walls of the lower electrode.

16. The semiconductor device according to claim 1, wherein, in the upper electrode, the titanium nitride film is formed to have a design thickness of 10 nm or more and a substantive thickness of about 8 nm or more on the dielectric film.

17. The semiconductor device according to claim 1, wherein the lower electrode comprises the titanium nitride film formed on the dielectric film, an impurity doped polysilicon film formed on the titanium nitride film, and a metal plate electrode.
